(19) United States
(12) Patent Application Publication
(10) Pub. No.: US 2018/0277564 A1
(43) Pub. Date: Sep. 27, 2018

(54) SEMICONDUCTOR MEMORY DEVICE AND METHOD FOR MANUFACTURING THE SAME

(71) Applicant: Toshiba Memory Corporation, Minato-ku (JP)

(72) Inventor: Hiroto SUGIURA, Yokkaichi (JP)

(73) Assignee: Toshiba Memory Corporation, Minato-ku (JP)

(21) Appl. No.: 15/703,095

(22) Filed: Sep. 13, 2017

(30) Foreign Application Priority Data
Mar. 23, 2017 (JP) 2017-058105

(51) Int. Cl. H01L 27/11582; H01L 27/11568; H01L 21/311; H01L 21/02; H01L 27/11573; H01L 23/00

(52) U.S. Cl. CPC H01L 27/11582; H01L 27/11568; H01L 21/31116; H01L 21/02636; H01L 21/0217; H01L 23/528; H01L 23/562; H01L 21/02164; H01L 21/31144; H01L 21/02532; H01L 27/11573

(57) ABSTRACT

According to an embodiment, a semiconductor memory device includes a substrate, a stacked body, a circuit section, a first insulating layer, and a first columnar part. The stacked body is provided on the substrate and includes a plurality of electrode layers stacked with spacing from each other. The circuit section is provided on the substrate and located in a second region adjacent to a first region provided with the stacked body. The first insulating layer is provided in the second region. The first columnar part is provided in the second region and extends in a stacking direction of the plurality of electrode layers. The first insulating layer is located between the circuit section and the first columnar part.

### CROSS-REFERENCE TO RELATED APPLICATIONS

This application is based upon and claims the benefit of priority from Japanese Patent Application No. 2017-058105, filed on Mar. 23, 2017; the entire contents of which are incorporated herein by reference.

### FIELD

Embodiments relate generally to a semiconductor memory device and a method for manufacturing the same.

### BACKGROUND

A semiconductor memory device with three-dimensional structure has a structure in which a memory cell array including a plurality of memory cells is integrated with a peripheral circuit. The memory cell array is provided with a stacked body in which a plurality of electrode layers are stacked. Memory holes are formed in the stacked body. The end part of the stacked body is processed into a staircase shape. An insulating layer is provided from the staircase-shaped end part to the peripheral circuit. Such thick formation of an insulating layer causes the problem of increased warpage of the substrate due to internal stress of the insulating layer.

### BRIEF DESCRIPTION OF THE DRAWINGS

FIG. 1A and FIG. 1B are sectional views showing a semiconductor memory device according to a first embodiment;

FIG. 2 is an enlarged view of region A of FIG. 1B;

FIG. 3 is an enlarged view of region B of FIG. 1A;

FIG. 4A and FIG. 4B are sectional views showing a method for manufacturing the semiconductor memory device according to the first embodiment;

FIG. 5A and FIG. 5B are sectional views showing the method for manufacturing the semiconductor memory device according to the first embodiment;

FIG. 6A and FIG. 6B are sectional views showing the method for manufacturing the semiconductor memory device according to the first embodiment;

FIG. 7A and FIG. 7B are sectional views showing the method for manufacturing the semiconductor memory device according to the first embodiment;

FIG. 8A and FIG. 8B are sectional views showing the method for manufacturing the semiconductor memory device according to the first embodiment;

FIG. 9A and FIG. 9B are sectional views showing the method for manufacturing the semiconductor memory device according to the first embodiment;

FIG. 10A and FIG. 10B are sectional views showing a semiconductor memory device according to a second embodiment;

FIG. 11 is an enlarged view of region C of FIG. 10A;

FIG. 12A and FIG. 12B are sectional views showing a method for manufacturing the semiconductor memory device according to the second embodiment;

FIG. 13A and FIG. 13B are sectional views showing the method for manufacturing the semiconductor memory device according to the second embodiment;

FIG. 14A and FIG. 14B are sectional views showing the method for manufacturing the semiconductor memory device according to the second embodiment;

FIG. 15A and FIG. 15B are sectional views showing the method for manufacturing the semiconductor memory device according to the second embodiment;

FIG. 16A and FIG. 16B are sectional views showing the method for manufacturing the semiconductor memory device according to the second embodiment;

FIG. 17A and FIG. 17B are sectional views showing the method for manufacturing the semiconductor memory device according to the second embodiment;

FIG. 18A and FIG. 18B are sectional views showing the method for manufacturing the semiconductor memory device according to the second embodiment; and

FIG. 19A and FIG. 19B are sectional views showing the method for manufacturing the semiconductor memory device according to the second embodiment.

### DETAILED DESCRIPTION

According to an embodiment, a semiconductor memory device includes a substrate, a stacked body, a circuit section, a first insulating layer, and a first columnar part. The stacked body is provided on the substrate and includes a plurality of electrode layers stacked with spacing from each other. The circuit section is provided on the substrate and located in a second region adjacent to a first region provided with the stacked body. The first insulating layer is provided in the second region. The first columnar part is provided in the second region and extends in a stacking direction of the plurality of electrode layers. The first insulating layer is located between the circuit section and the first columnar part.

Embodiments of the invention will now be described with reference to the drawings.

The drawings are schematic or conceptual; and the relationships between the thicknesses and widths of portions, the proportions of sizes between portions, etc., are not necessarily the same as the actual values thereof. The dimensions and/or the proportions may be illustrated differently between the drawings, even in the case where the same portion is illustrated.

In the drawings and the specification of the application, components similar to those described thereinabove are marked with like reference numerals, and a detailed description is omitted as appropriate.

### First Embodiment

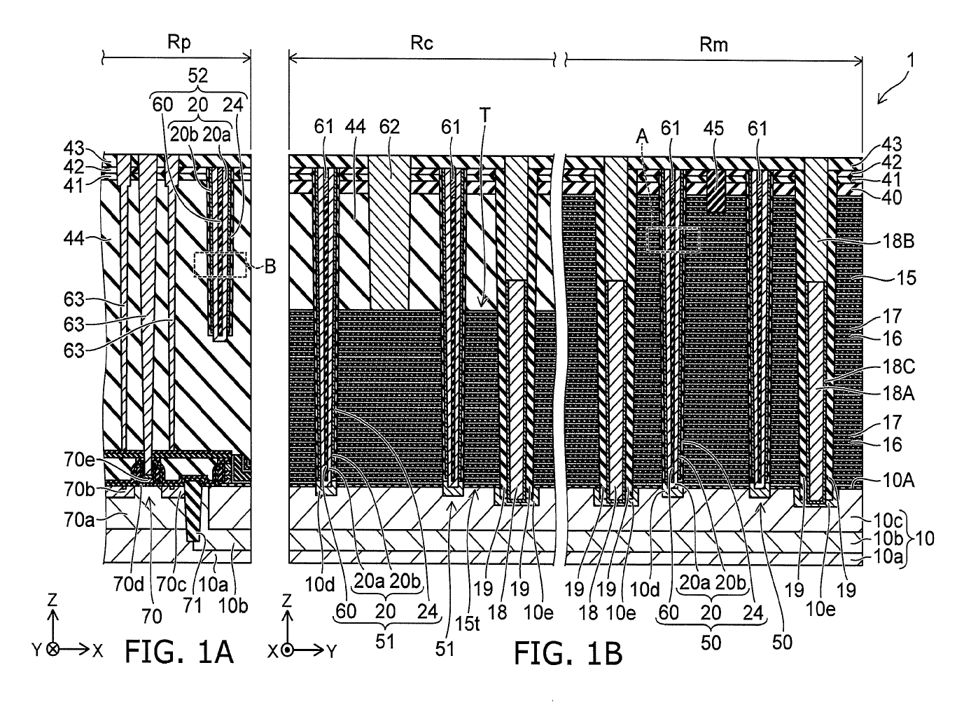

FIGS. 1A and 1B are sectional views of a semiconductor memory device 1.

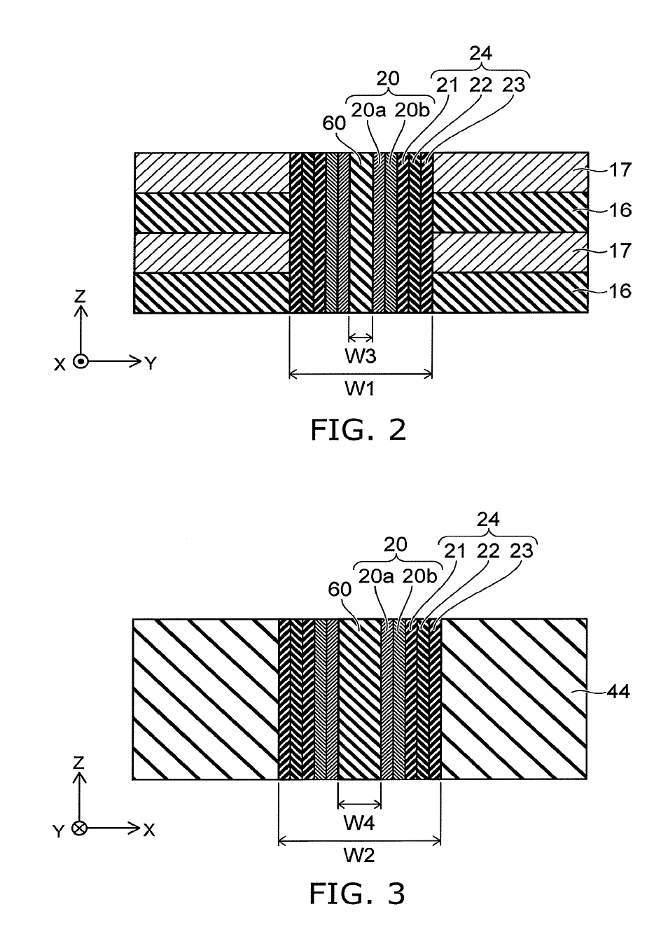

FIG. 2 is an enlarged view of region A of FIG. 1B. FIG. 3 is an enlarged view of region B of FIG. 1A.

As shown in FIGS. 1A and 1B, the semiconductor memory device 1 is provided with a semiconductor substrate 10.

Here, in this specification, two directions parallel to the upper surface 10A of the semiconductor substrate 10 and orthogonal to each other are referred to as X-direction and Y-direction. The direction orthogonal to both the X-direction and the Y-direction is referred to as Z-direction. FIGS. 1A and 1B show an X-Z cross section and a Y-Z cross section of the semiconductor memory device 1, respectively.

The semiconductor memory device 1 is provided with a memory cell region Rm, a staircase region Rc, and a peripheral region Rp. The peripheral region Rp, the staircase region Rc, and the memory cell region Rm are placed sequentially along the X-direction.

As shown in FIG. 1B, the memory cell region Rm is provided with a stacked body 15, a columnar part 50, and an interconnect part 18.

The stacked body 15 is provided on the semiconductor substrate 10. The semiconductor substrate 10 contains e.g. silicon (Si). The semiconductor substrate 10 includes a P-type substrate 10a, an N-well region 10b, and a P-well region 10c. The N-well region 10b is provided on the P-type substrate 10a. The P-well region 10c is provided on the N-well region 10b.

The stacked body 15 includes a plurality of electrode layers 17 and a plurality of insulating layers 16. For instance, the electrode layer 17 contains e.g. metal such as tungsten (W), and the insulating layer 16 contains e.g. silicon oxide (SiO). The insulating layer 16 is provided between each pair of the electrode layers 17. The number of stacked electrode layers 17 is arbitrary.

Insulating layers 40, 41, 42, 43 are sequentially provided on the stacked body 15. The insulating layers 40, 41, 42, 43 contain e.g. silicon oxide.

The columnar part 50 is provided in a plurality in the stacked body 15. The columnar part 50 extends in the Z-direction in the stacked body 15 and in the insulating layers 40, 41, 42. The columnar part 50 is shaped like e.g. a circular column or an elliptic column. The columnar part 50 includes a core part 60, a channel 20, and a memory film 24.

The core part 60 contains e.g. silicon oxide. The core part 60 is shaped like e.g. a circular column. The columnar part 50 may not be provided with the core part 60.

A plug part 61 is provided at the upper end of the core part 60. The plug part 61 is located in the upper part of the stacked body 15 and in the insulating layer 40. The side surface of the plug part 61 is surrounded with the channel 20. The plug part 61 contains e.g. polysilicon crystallized from amorphous silicon.

The channel 20 is provided on the side surface of the core part 60. The channel 20 is a semiconductor part and includes a body 20a and a cover layer 20b. The body 20a is shaped like e.g. a tube having a bottom. The cover layer 20b is provided on the side surface of the body 20a. The cover layer 20b is shaped like e.g. a tube. The body 20a and the cover layer 20b contain silicon such as polysilicon crystallized from amorphous silicon.

The lower end of the channel 20 is in contact with the semiconductor substrate 10. For instance, the lower end of the channel 20 is in contact with a connection member 10d formed in the semiconductor substrate 10. The connection member 10d is a member formed in the P-well region 10c of the semiconductor substrate 10. For instance, the connection member 10d is a member formed by epitaxial growth of silicon.

The memory film 24 is provided on the side surface of the channel 20. As shown in FIG. 2, the memory film 24 includes a tunnel insulating film 21, a charge storage film 22, and a block insulating film 23.

The tunnel insulating film 21 is provided on the side surface of the channel 20. The tunnel insulating film 21 contains e.g. silicon oxide. The tunnel insulating film 21 is shaped like e.g. a circular cylinder.

The charge storage film 22 is provided on the side surface of the tunnel insulating film 21. The charge storage film 22 contains e.g. silicon nitride (SiN). The charge storage film 22 is shaped like e.g. a circular cylinder. A memory cell including the charge storage film 22 is formed in the crossing portion of the channel 20 and the electrode layer 17.

The tunnel insulating film 21 is a potential barrier between the charge storage film 22 and the channel 20. The tunnel insulating film 21 allows charges to tunnel therethrough when charges move from the channel 20 to the charge storage film 22 (write operation) and when charges move from the charge storage film 22 to the channel 20 (erase operation).

The charge storage film 22 includes trap sites for trapping charges in the film. The threshold of the memory cell varies with the presence or absence of charges trapped in the trap sites, and the amount of trapped charges. This allows the memory cell to retain information.

The block insulating film 23 is provided on the side surface of the charge storage film 22. The block insulating film 23 contains e.g. silicon oxide. The block insulating film 23 protects e.g. the charge storage film 22 from being etched when the electrode layer 17 is formed. The block insulating film 23 may be a stacked film of a silicon oxide film and an aluminum oxide film.

A plurality of bit lines (not shown) extending in the Y-direction are provided above the columnar part 50. The bit line is connected to the columnar part 50 through a contact connected to the plug part 61.

The interconnect part 18 is provided in a plurality in the stacked body 15. The interconnect part 18 extends in the X-direction and the Z-direction in the stacked body 15 and in the insulating layers 40, 41, 42, 43. The interconnect part 18 includes a conductive part 18A, a conductive part 18B, and a peripheral part 18C.

The conductive part 18B is provided on the conductive part 18A. The conductive part 18A contains e.g. silicon. For instance, silicon is polysilicon crystallized from amorphous silicon. The conductive part 18B contains e.g. tungsten.

The peripheral part 18C covers the side surface and the bottom surface of the conductive part 18A. The peripheral part 18C is e.g. a barrier metal layer containing titanium nitride (TiN).

An insulative sidewall 19 is provided on the side surface of the interconnect part 18. The sidewall 19 contains e.g. silicon oxide. The sidewall 19 provides electrical isolation between the interconnect part 18 and the electrode layer 17 of the stacked body 15.

An insulating member 45 extending in the X-direction is provided between the interconnect parts 18 adjacent in the Y-direction. Part of the insulating member 45 is placed in the upper part of the stacked body 15 and divides each of one or more electrode layers 17 from the top into two. The divided electrode layer 17 functions as an upper select gate line. The insulating member 45 contains e.g. silicon oxide or silicon nitride.

The lower end of the interconnect part 18 is in contact with the semiconductor substrate 10. For instance, the lower end of the interconnect part 18 is in contact with a connection member 10e formed in the semiconductor substrate 10. The connection member 10e is a member formed in the P-well region 10c of the semiconductor substrate 10. For instance, the connection member 10e is formed by implantation of impurity such as boron (B).

A source line (not shown) is provided above the interconnect part 18. The source line is connected to the interconnect part 18 through a contact.

As shown in FIG. 1B, the staircase region Rc is provided with a stacked body 15, a columnar part 51, and an interconnect part 18.

The end part 15t of the stacked body 15 is located in the staircase region Rc. The end part 15t is shaped like a staircase in which a terrace T is formed in the electrode layer 17. An insulating layer 44 is provided between the end part 15t and the insulating layer 40. The insulating layer 44 contains e.g. silicon oxide. The insulating film 44 is formed from e.g. TEOS (tetraethoxysilane) as a raw material.

A contact 62 is provided on the terrace T of the electrode layer 17. The contact 62 extends in the Z-direction in the insulating layer 44 and in the insulating layers 40, 41, 42, 43. The lower end of the contact 62 is connected to the terrace T of the electrode layer 17. The upper end of the contact 62 is connected to an upper interconnect (not shown). The contact 62 contains a conductive material, e.g., metal such as tungsten.

The columnar part 51 is provided in a plurality in the end part 15t of the stacked body 15. The columnar part 51 extends in the Z-direction in the end part 15t of the stacked body 15 and in the insulating layers 40, 41, 42, 44. The columnar part 51 is shaped like e.g. a circular column or an elliptic column. The columnar part 51 contains the same material as the columnar part 50 is formed from. That is, the columnar part 51 includes a core part 60, a channel 20, and a memory film 24.

The lower end of the channel 20 of the columnar part 51 is in contact with the semiconductor substrate 10. For instance, the lower end of the channel 20 is in contact with a connection member 10d formed in the semiconductor substrate 10.

As shown in FIG. 1A, the peripheral region Rp is provided with a circuit section 70 and a columnar part 52.

The circuit section 70 is provided on the P-type substrate 10a of the semiconductor substrate 10. The circuit section 70 includes a channel region 70a, a source region 70b, a drain region 70c, a gate insulating film 70d, and a gate electrode 70e.

The source region 70b and the drain region 70c are spaced from each other. The channel region 70a is located between the source region 70b and the drain region 70c. The gate insulating film 70d is provided on the channel region 70a. The gate electrode 70e is provided on the gate insulating film 70d.

The channel region 70a, the source region 70b, the drain region 70c, the gate insulating film 70d, and the gate electrode 70e constitute a transistor. A plurality of transistors are placed to constitute the circuit section 70.

The N-well region 10b and the P-well region 10c are sequentially provided on the P-type substrate 10a. STI (shallow trench isolation) 71 is provided in a trench extending in the Y-direction and the Z-direction. The STI 71 separates the channel region 70a, the source region 70b, and the drain region 70c from the N-well region 10b and the P-well region 10c. Thus, the semiconductor substrate 10 including the P-type substrate 10a, the N-well region 10b, and the P-well region 10c is configured.

A plurality of contacts 63 are provided on the circuit section 70. The contact 63 extends in the Z-direction in the insulating layer 44 and in the insulating layers 41, 42, 43. The contact 63 contains a conductive material, e.g., metal such as tungsten.

The lower end of the contact 63 is connected to an element such as the gate electrode 70e in the circuit section 70. The upper end of the contact 63 is connected to the upper interconnect (not shown). The circuit section 70 is connected to the electrode layer 17 (terrace T) through the contacts 62, 63 and the upper interconnect.

The columnar part 52 is provided in the insulating layer 44. The columnar part 52 extends in the Z-direction in the insulating layers 41, 42, 44. The columnar part 52 is shaped like e.g. a circular column or an elliptic column. The columnar part 52 may be shaped like a rectangular column, or a plate extending in the Y-direction and the Z-direction. The number of columnar parts 52 is arbitrary.

The columnar part 52 contains the same material as the columnar parts 50, 51 are formed from. That is, the columnar part 52 includes a core part 60, a channel 20, and a memory film 24. The channel 20 includes a body 20a and a cover layer 20b. As shown in FIG. 3, the memory film 24 includes a tunnel insulating film 21, a charge storage film 22, and a block insulating film 23.

For instance, as shown in FIGS. 2 and 3, the width W1 of the columnar part 50 is smaller than the width W2 of the columnar part 52. In this case, the width W3 of the core part 60 of the columnar part 50 is smaller than the width W4 of the core part 60 of the columnar part 52. For instance, the columnar parts 50, 52 are not provided with the core part 60. In this case, the width of the channel 20 of the columnar part 50 is smaller than the width of the channel 20 of the columnar part 52. For instance, the width W2 of the columnar part 52 is generally equal to the width of the columnar part 51.

Depending on the number of stacked electrode layers 17 of the stacked body 15, the width (W2) of the columnar part 52 may be smaller than the width (W1) of the columnar part 50 and the width of the columnar part 51. A void may be formed at least in part of the columnar part 52.

In the columnar part 52, the lower end of the channel 20 is located in the insulating layer 44. For instance, the lower end of the channel 20 is in contact with the insulating layer 44.

In the columnar part 52, the insulating layer 43 is located on the upper end of the channel 20 and on the upper end of the memory film 24. For instance, the upper end of the channel 20 and the upper end of the memory film 24 are in contact with the insulating layer 43.

Thus, the columnar part 52 is located in the insulating layer 44. Accordingly, part of the insulating layer 44 extending in the X-direction is divided by the columnar part 52.

In the peripheral region Rp, the columnar part 52 is preferably formed with a prescribed spacing in the X-direction and the Y-direction from the formation region of the contact 63. This can suppress contact between the columnar part 52 and the contact 63.

The Z-direction width of the columnar part 52 is arbitrary. However, the width of the columnar part 52 is preferably set so that the columnar part 52 is formed with a prescribed spacing in the Z-direction from the circuit section 70. This can suppress contact between the columnar part 52 and the circuit section 70.

In the memory cell region Rm, numerous memory cells are arranged in a three-dimensional matrix along the X-direction, the Y-direction, and the Z-direction. Data can be stored in each memory cell. On the other hand, in the staircase region Rc and the peripheral region Rp, each electrode layer 17 is extracted from the memory cell region Rm and connected to the circuit section 70 through the contact 62, 63 and the upper interconnect.

Next, a manufacturing method of the semiconductor memory device according to this embodiment is described.

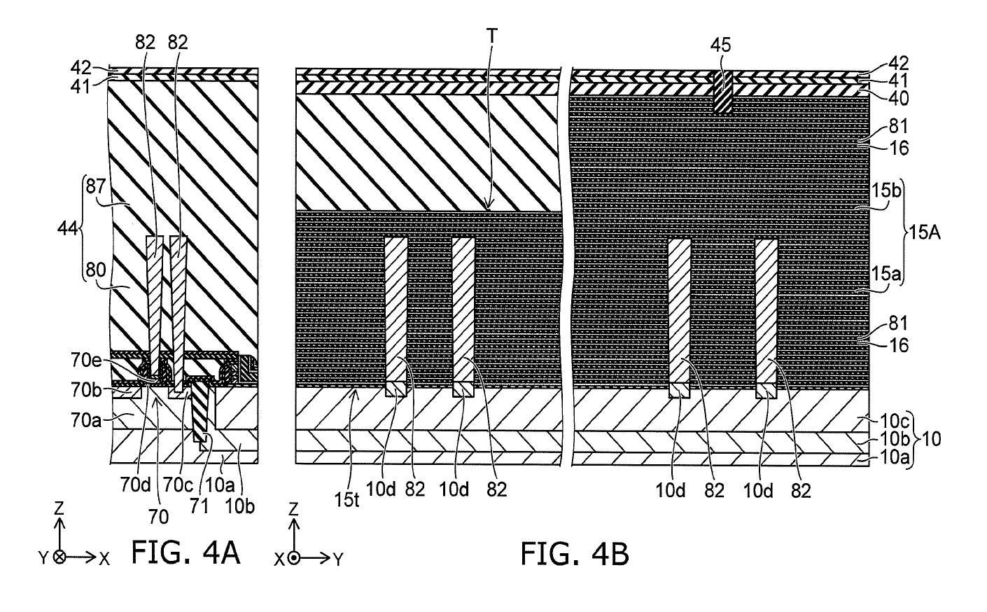

FIGS. 4A and 4B to 9A and 9B are sectional views showing a manufacturing method of the semiconductor memory device 1. FIGS. 4A to 9A show a region corresponding to part of FIG. 1A. FIGS. 4B to 9B show a region corresponding to FIG. 1B.

The process up to the step of forming the columnar parts 50, 51, 52 is described with reference to FIGS. 4A and 4B to 9A and 9B.

First, as shown in FIG. 4A, in the peripheral region Rp, a circuit section 70 is formed on a semiconductor substrate 10. The circuit section 70 is formed by well-known methods. In the circuit section 70, a channel region 70a, a source region 70b, and a drain region 70c are formed on a P-type substrate 10a. Furthermore, a gate insulating film 70d is formed on the channel region 70a, and a gate electrode 70e is formed on the gate insulating film 70d. The channel region 70a, the source region 70b, the drain region 70c, the gate insulating film 70d, and the gate electrode 70e forms a transistor. The circuit section 70 is formed by placing a plurality of such transistors. Then, an insulating layer 80 is formed on the circuit section 70. The insulating layer 80 is formed from e.g. TEOS.

On the other hand, as shown in FIGS. 4A and 4B, in the memory cell region Rm, the staircase region Rc, and the peripheral region Rp, an N-well region 10b and a P-well region 10c are sequentially formed on the P-type substrate 10a. Subsequently, in the peripheral region Rp, STI 71 is formed in a trench extending in the Y-direction and the Z-direction. The STI 71 separates the channel region 70a, the source region 70b, and the drain region 70c from the N-well region 10b and the P-well region 10c. Thus, the semiconductor substrate 10 including the P-type substrate 10a, the N-well region 10b, and the P-well region 10c is formed.

Subsequently, in the memory cell region Rm and the staircase region Rc, a stacked body 15a is formed by stacking insulating layers 16 and sacrificial layers 81 alternately along the Z-direction on the semiconductor substrate 10 by e.g. the CVD (chemical vapor deposition) method. For instance, the insulating layer 16 is formed from silicon oxide, and the sacrificial layer 81 is formed from silicon nitride. Then, in the memory cell region Rm and the staircase region Rc, through holes are formed in the stacked body 15a. In the peripheral region Rp, through holes are formed in the insulating layer 80. A sacrificial layer 82 is formed in these through holes. The sacrificial layer 82 is formed from e.g. amorphous silicon. In the memory cell region Rm and the staircase region Rc, after forming the through holes, a connection member 10d is formed by e.g. epitaxial growth of silicon from the P-well region 10c of the semiconductor substrate 10 to the inside of the stacked body 15a.

Subsequently, in the memory cell region Rm, a stacked body 15b is formed by stacking insulating layers 16 and sacrificial layers 81 alternately along the Z-direction on the stacked body 15a. Thus, a stacked body 15A including the stacked body 15a and the stacked body 15b is formed. Then, in the staircase region Rc, the stacked body 15A is processed into a staircase shape. Such a staircase-shaped portion is formed by repeating the step of etching a resist film on the stacked body 15A to control the etching amount of the stacked body 15A and then etching the stacked body 15A downward. Thus, the end part 15t of the stacked body 15A formed on the semiconductor substrate 10 is processed into a staircase shape, and a terrace T is formed for each sacrificial layer 81.

Subsequently, in the staircase region Rc and the peripheral region Rp, an insulating layer 87 is formed. The insulating layer 87 is formed from e.g. TEOS. Thus, an insulating layer 44 including the insulating layers 80, 87 is formed. Then, in the memory cell region Rm, insulating layers 40, 41, 42 are sequentially formed on the stacked body 15A. In the staircase region Rc, insulating layers 40, 41, 42 are sequentially formed on the insulating layer 44. On the other hand, in the peripheral region Rp, insulating layers 41, 42 are sequentially formed on the insulating layer 44.

Subsequently, in the memory cell region Rm, a trench extending in the X-direction and the Z-direction is formed from the upper surface of the insulating layer 42. An insulating member 45 is formed in the trench.

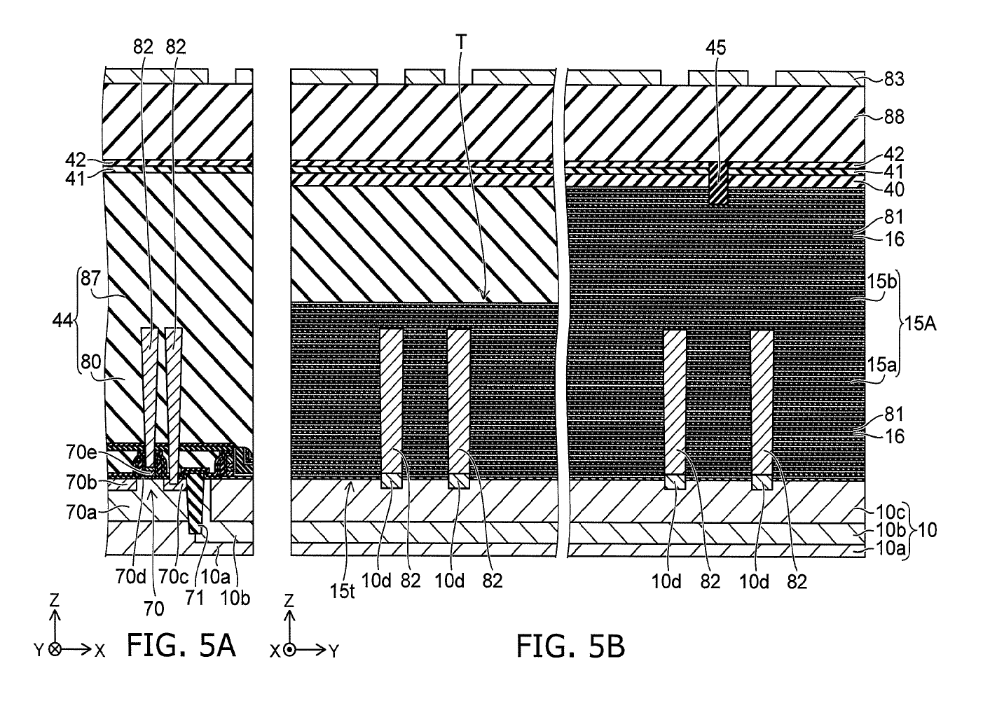

Next, as shown in FIGS. 5A and 5B, in the memory cell region Rm, the staircase region Rc, and the peripheral region Rp, an insulating layer 88 is formed on the insulating layer 42. A resist film 83 is formed on the insulating layer 88. Subsequently, the resist film 83 is patterned.

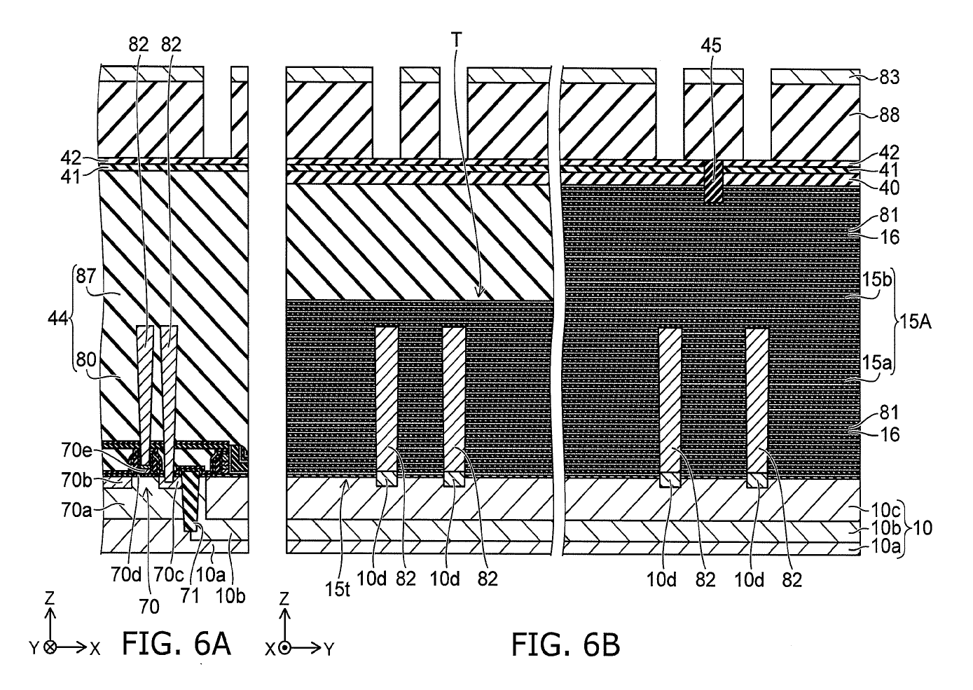

Next, as shown in FIGS. 6A and 6B, in the memory cell region Rm, the staircase region Rc, and the peripheral region Rp, part of the insulating layer 88 is removed by etching processing such as RIE (reactive ion etching) using the resist film 83 as a mask. Thus, the upper surface of the insulating layer 42 is exposed in each region.

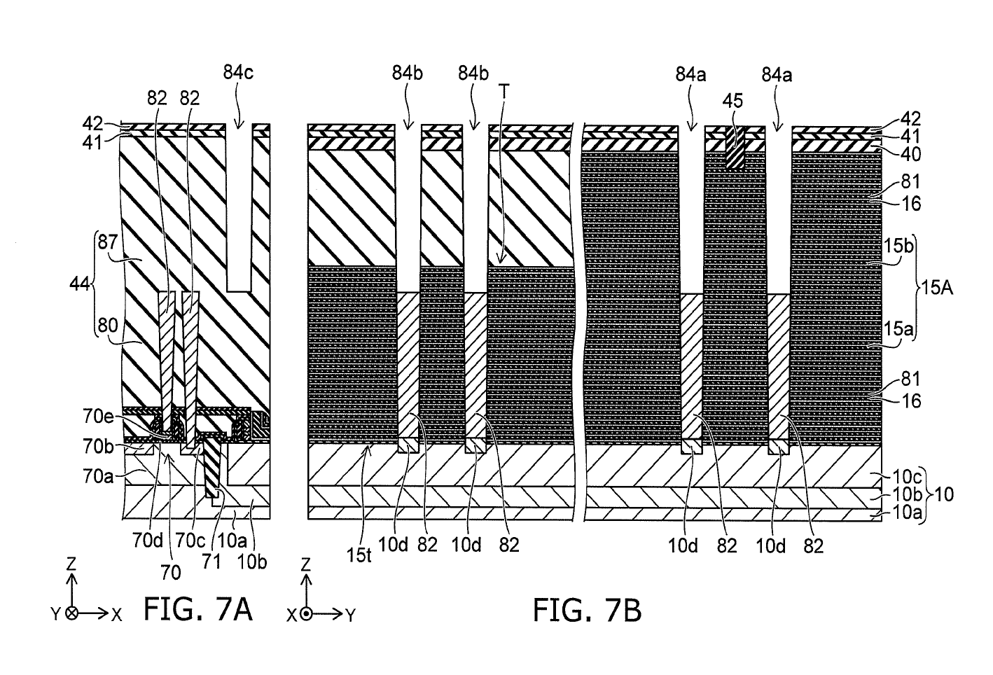

Next, as shown in FIGS. 7A and 7B, in the memory cell region Rm, the staircase region Rc, and the peripheral region Rp, etching processing such as RIE is performed from the exposed upper surface of the insulating layer 42. Thus, holes 84a, 84b, 84c are formed in the memory cell region Rm, the staircase region Rc, and the peripheral region Rp, respectively. In the memory cell region Rm and the staircase region Rc, the holes 84a, 84b are formed so as to be located directly above the sacrificial layer 82. On the other hand, in the peripheral region Rp, the hole 84c is formed so as to be located in the insulating layer 44. That is, the bottom surface and the side surface of the hole 84c are surrounded with the insulating layer 44.

Then, the insulating layer 88 and the resist film 83 are removed.

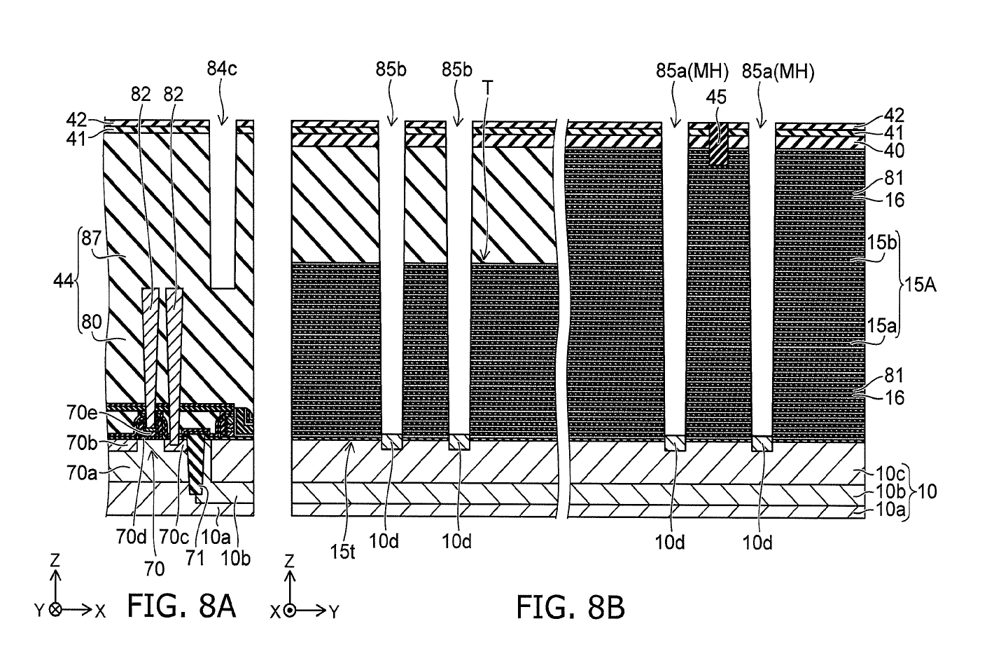

Next, as shown in FIGS. 8A and 8B, in the memory cell region Rm and the staircase region Rc, the sacrificial layers 82 located directly below the holes 84a, 84b are removed through the holes 84a, 84b. Thus, a through hole 85a (memory hole MH) is formed in the memory cell region Rm, and a through hole 85b is formed in the staircase region Rc.

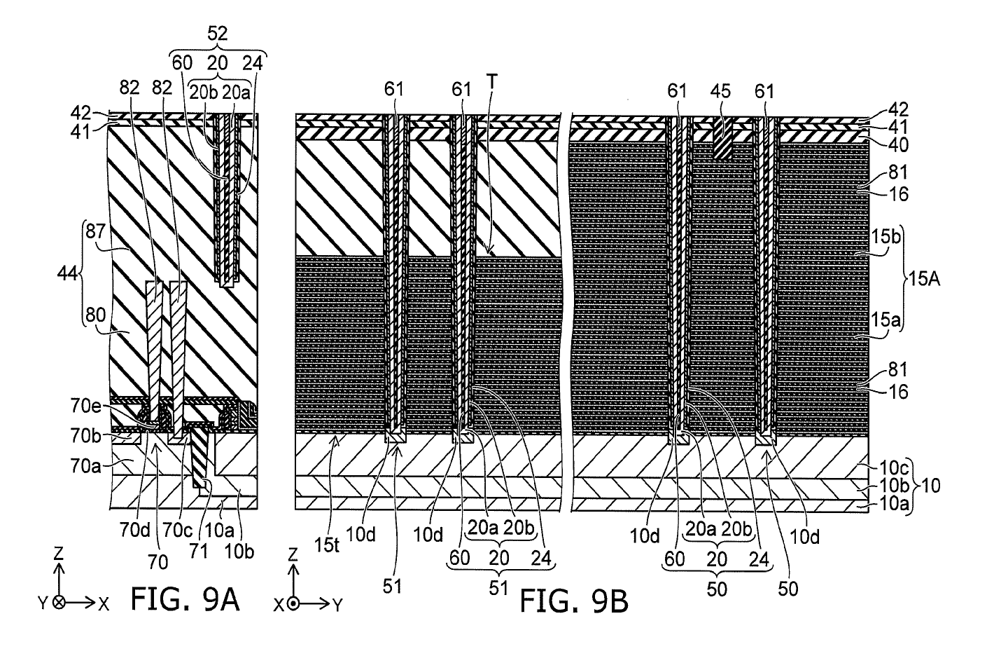

Next, as shown in FIGS. 9A and 9B, in the memory cell region Rm, the staircase region Rc, and the peripheral region Rp, by e.g. the CVD method, on the inner surface of the through holes 85a, 85b and the hole 84c, silicon oxide is deposited to form a block insulating film 23 (see FIGS. 2 and 3), silicon nitride is deposited to form a charge storage film 22 (see FIGS. 2 and 3), and silicon oxide is deposited to form a tunnel insulating film 21 (see FIGS. 2 and 3).

Subsequently, silicon is deposited to form a cover layer 20b. Then, by performing RIE, the cover layer 20b, the tunnel insulating film 21, the charge storage film 22, and the block insulating film 23 are removed to expose the connection member 10d and the insulating layer 44. Thus, a memory film 24 is formed.

Subsequently, in the through holes 85a, 85b and in the hole 84c, silicon is deposited to form a body 20a, and silicon oxide is deposited to form a core part 60. Thus, a channel 20 is formed. Accordingly, columnar parts 50, 51, 52 each including the core part 60, the channel 20, and the memory film 24 are formed. In the channel 20 of the columnar parts 50, 51, the body 20a is in contact with the connection member 10d formed in the semiconductor substrate 10. For instance, in the channel 20 of the columnar part 52, the lower end of the body 20a is in contact with the insulating layer 44.

Subsequently, etch-back is performed to remove the upper part of the core part 60 in the through holes 85a, 85b and in the hole 84c. Impurity-doped silicon is buried therein to form a plug part 61.

Then, in the memory cell region Rm, the staircase region Rc, and the peripheral region Rp, an insulating layer 43 is formed on the insulating layer 42.

Subsequently, in the memory cell region Rm and the staircase region Rc, a plurality of slits extending in the X-direction and the Z-direction are formed in the stacked body 15a. The sacrificial layers 81 are removed by performing etching processing through the slits. Subsequently, metal such as tungsten is deposited in the void formed by the removal of the sacrificial layers 81 to form electrode layers 17. Thus, the sacrificial layers 81 of the stacked body 15A are replaced by the electrode layers 17. Accordingly, a stacked body 15 is formed.

Subsequently, in the memory cell region Rm and the staircase region Rc, silicon oxide is deposited on the slit inner surface to form a sidewall 19 (see FIG. 1B). Then, titanium nitride is deposited to form a peripheral part 18C. Then, silicon is deposited to form a conductive part 18A, and metal such as tungsten is deposited to form a conductive part 18B. Thus, an interconnect part 18 (see FIG. 1B) is formed.

Subsequently, in the staircase region Rc, a contact hole is formed through the insulating layers 43, 42, 41, 40 and the insulating layer 44. In the peripheral region Rp, a contact hole is formed through the insulating layers 43, 42, 41 and the insulating layer 44. Then, a metal material such as tungsten is buried in these contact holes to form contacts 62, 63 (see FIGS. 1A and 1B).

Thus, the semiconductor memory device 1 of this embodiment is manufactured.

In the manufacturing method of the semiconductor memory device 1 of this embodiment, the columnar part 50 is formed by alternately performing formation of the stacked body and formation of the hole. However, the columnar part 50 may be formed by forming a memory hole MH once after formation of the stacked body. In this case, the columnar part 52 is formed by forming a hole 84c when forming the memory hole MH.

Next, the effect of this embodiment is described.

In a semiconductor memory device with three-dimensional structure, from the staircase region to the peripheral region, an insulating layer formed from a raw material such as TEOS is provided so as to cover the staircase-shaped end part and the circuit section. Thickly providing such an insulating layer in the staircase region and the peripheral region may cause large warpage of the substrate due to internal stress (e.g. compressive stress) by the insulating layer. Large warpage of the substrate lowers the processing accuracy in the manufacturing process (such as the step of forming a circuit section on the substrate and the step of forming a contact and an interconnect in the circuit section). This results in hampering stable operation of the manufacturing apparatus.

The semiconductor memory device 1 of this embodiment includes a columnar part 52 provided in the insulating layer 44 of the peripheral region Rp. The columnar part 52 is provided with a prescribed spacing in the Z-direction from the circuit section 70 so that the insulating layer 44 is located between the columnar part 52 and the circuit section 70 on the semiconductor substrate 10. Thus, the insulating layer 44 thickly formed and extending in the X-direction is partly divided in the peripheral region Rp. Accordingly, the volume of the insulating layer 44 is decreased. Thus, the internal stress (e.g. compressive stress) by the insulating layer 44 is relaxed. This suppresses warpage of the semiconductor substrate 10 and suppresses lowering of the processing accuracy in the manufacturing process. Providing the columnar part 52 with a prescribed spacing in the Z-direction from the circuit section 70 suppresses contact between the columnar part 52 and the circuit section 70.

This embodiment provides a semiconductor memory device and a manufacturing method thereof with improved reliability.

### Second Embodiment

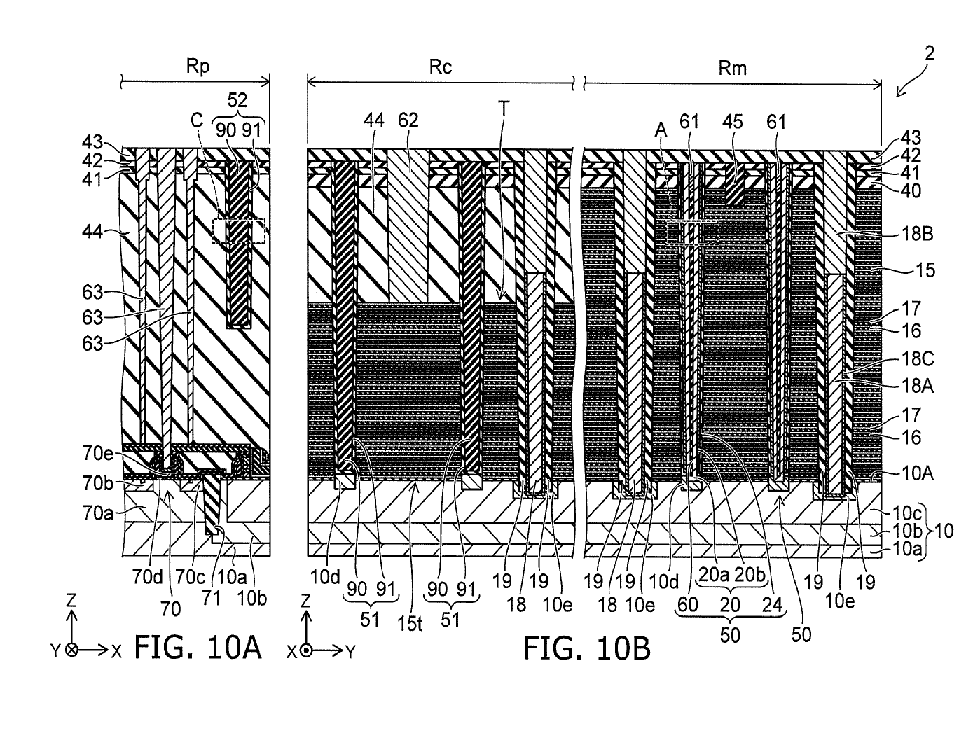

FIGS. 10A and 10B are sectional views of a semiconductor memory device 2.

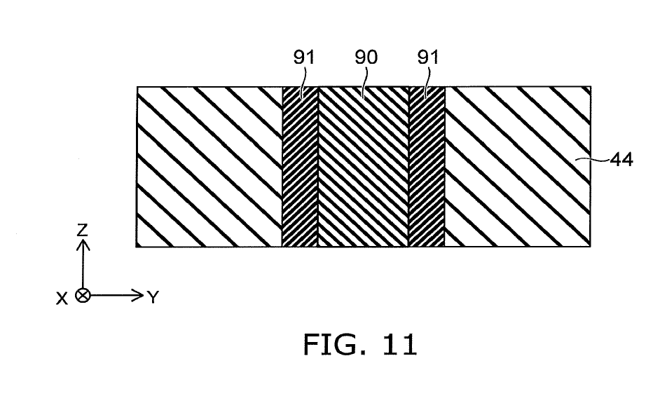

FIG. 11 is an enlarged view of region C of FIG. 10A.

The regions shown in FIGS. 10A and 10B correspond to the regions shown in FIGS. 1A and 1B, respectively.

The semiconductor memory device 2 according to this embodiment is different from the semiconductor memory device 1 according to the first embodiment in the formation material of the columnar parts 51, 52. The rest of the formation material of the columnar parts 51, 52 is the same as the first embodiment. Thus, detailed description of the remaining configuration is omitted.

As shown in FIGS. 10A and 10B, the semiconductor memory device 2 is provided with a memory cell region Rm, a staircase region Rc, and a peripheral region Rp. The columnar part 51 and the columnar part 52 are provided in the staircase region Rc and the peripheral region Rp.

As shown in FIG. 11, the columnar part 52 includes an insulating film 90 and an insulating film 91.

The insulating film 90 is formed from a material having a stress (e.g. tensile stress) for relaxing the internal stress (e.g. compressive stress) by the insulating layer 44. The insulating film 90 contains e.g. silicon nitride. The insulating film 90 is shaped like e.g. a circular column.

The insulating film 91 is provided on the bottom surface and the side surface of the insulating film 90. The insulating film 91 is a film for protecting the insulating film 90. The insulating film 91 contains e.g. silicon oxide. The insulating film 91 is shaped like e.g. a tube having a bottom.

The columnar part 51 contains the same material as the columnar part 52 is formed from. That is, the columnar part 51 includes an insulating film 90 and an insulating film 91.

In the columnar part 51, the bottom surface of the insulating film 91 is located in the stacked body 15. For instance, the bottom surface of the insulating film 91 is in contact with the connection member 10d.

In the columnar part 51, the insulating layer 43 is located on the upper surface of the insulating film 90 and on the upper surface of the insulating film 91. For instance, the upper surface of the insulating film 90 and the upper surface of the insulating film 91 are in contact with the insulating layer 43.

In the columnar part 52, the bottom surface of the insulating film 91 is located in the insulating layer 44. For instance, the bottom surface of the insulating film 91 is in contact with the insulating layer 44.

In the columnar part 52, the insulating layer 43 is located on the upper surface of the insulating film 90 and on the upper surface of the insulating film 91. For instance, the upper surface of the insulating film 90 and the upper surface of the insulating film 91 are in contact with the insulating layer 43.

Thus, the columnar part 52 is located in the insulating layer 44. Accordingly, the columnar part 52 divides part of the insulating layer 44 extending in the X-direction.

Next, a manufacturing method of the semiconductor memory device according to this embodiment is described.

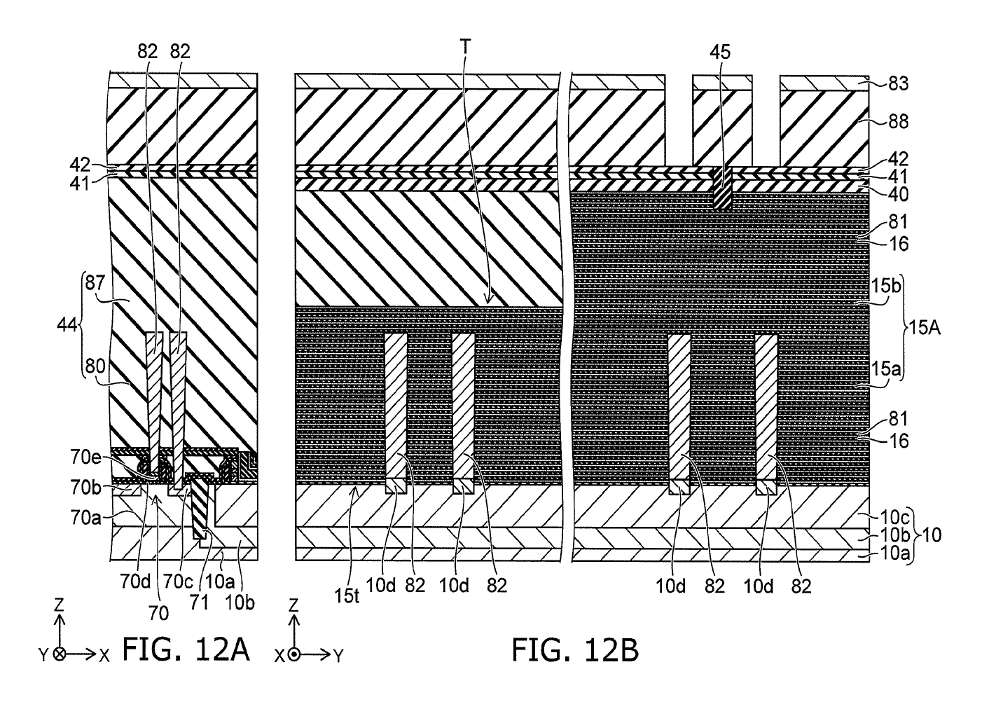

FIGS. 12A and 12B to 19A and 19B are sectional views showing a manufacturing method of the semiconductor memory device 2. FIGS. 12A to 19A show a region corresponding to part of FIG. 10A. FIGS. 12B to 19B show a region corresponding to FIG. 10B.

The process up to the step of forming the columnar parts 50, 51, 52 is described with reference to FIGS. 12A and 12B to 19A and 19B. The manufacturing method of the semiconductor memory device of this embodiment is the same as the manufacturing method of the semiconductor memory device of the first embodiment before the step of forming the insulating layer 88 and the resist film 83. Thus, detailed description of the step of FIGS. 4A and 4B is omitted.

After the step of FIGS. 4A and 4B, as shown in FIGS. 12A and 12B, in the memory cell region Rm, the staircase region Rc, and the peripheral region Rp, an insulating layer 88 is formed on the insulating layer 42. A resist film 83 is formed on the insulating layer 88. Subsequently, as shown in FIG. 12B, in the memory cell region Rm, the resist film 83 is patterned. Part of the insulating layer 88 is removed by etching processing using the resist film 83 as a mask. Thus, the upper surface of the insulating layer 42 is exposed.

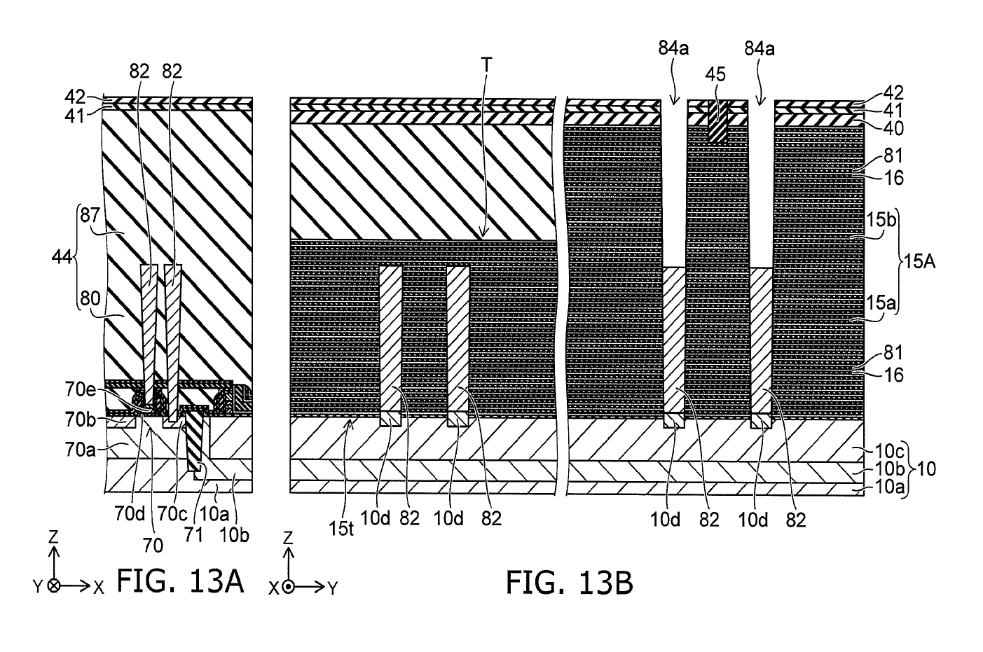

Next, as shown in FIGS. 13A and 13B, in the memory cell region Rm, etching processing is performed from the exposed upper surface of the insulating layer 42. Then, in the memory cell region Rm, the staircase region Rc, and the peripheral region Rp, the insulating layer 88 and the resist film 83 are removed. Thus, a hole 84a located directly above the sacrificial layer 82 is formed in the memory cell region Rm.

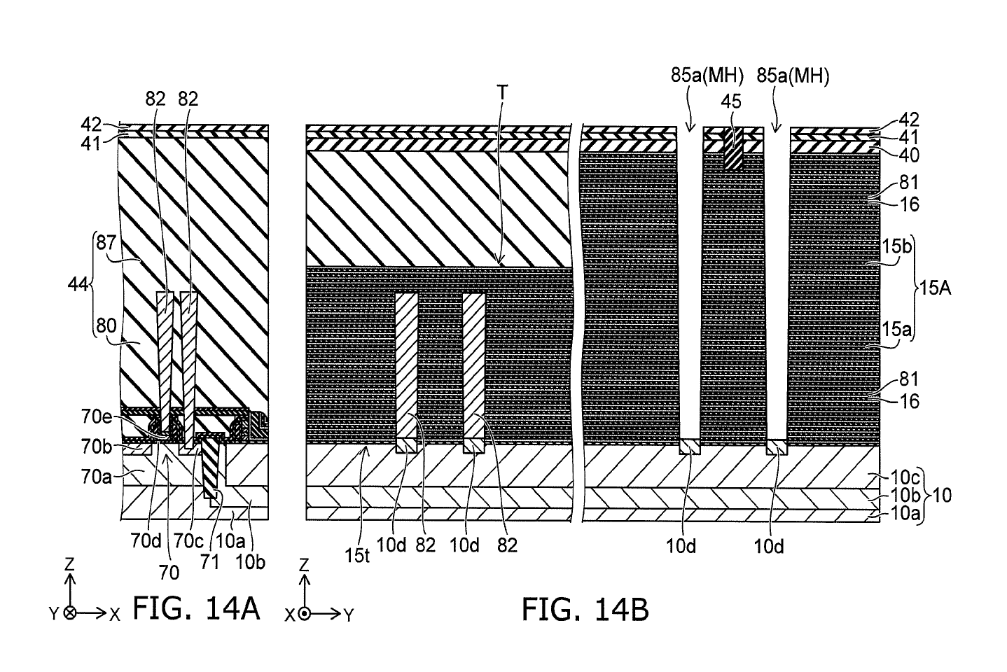

Next, as shown in FIGS. 14A and 14B, in the memory cell region Rm, the sacrificial layer 82 located directly below the hole 84a is removed through the hole 84a. Thus, a through hole 85a (memory hole MH) is formed in the memory cell region Rm.

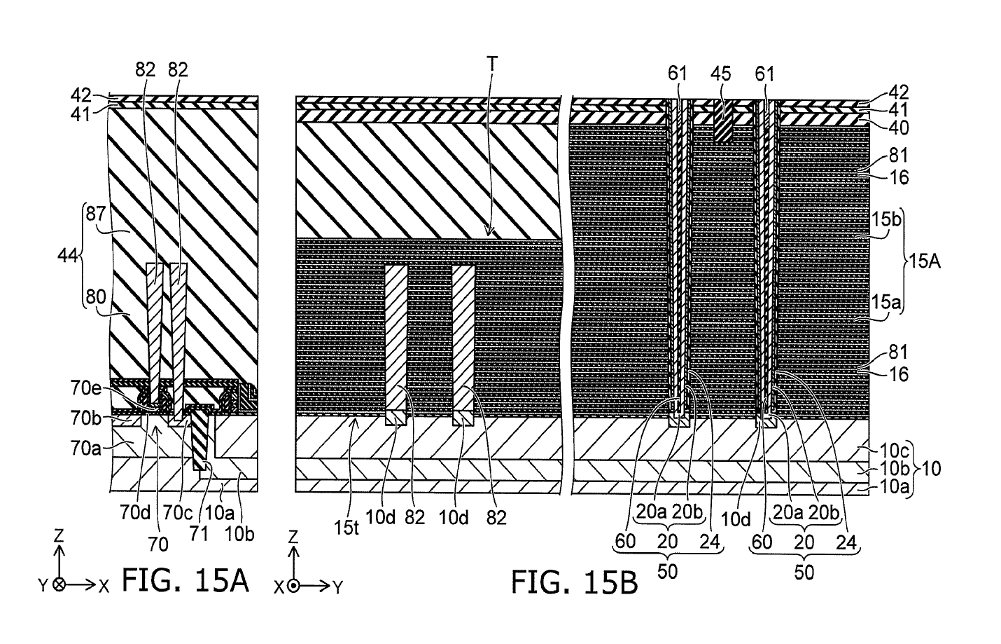

Next, as shown in FIGS. 15A and 15B, in the memory cell region Rm, a block insulating film 23, a charge storage film 22, and a tunnel insulating film 21 are sequentially formed in the through hole 85a. Then, a cover layer 20b is formed. Then, after exposing the connection member 10d by etching, a body 20a and a core part 60 are sequentially formed. Thus, a columnar part 50 including the core part 60, the channel 20, and the memory film 24 is formed. Subsequently, the upper part of the core part 60 in the through hole 85a is removed, and a plug part 61 is formed.

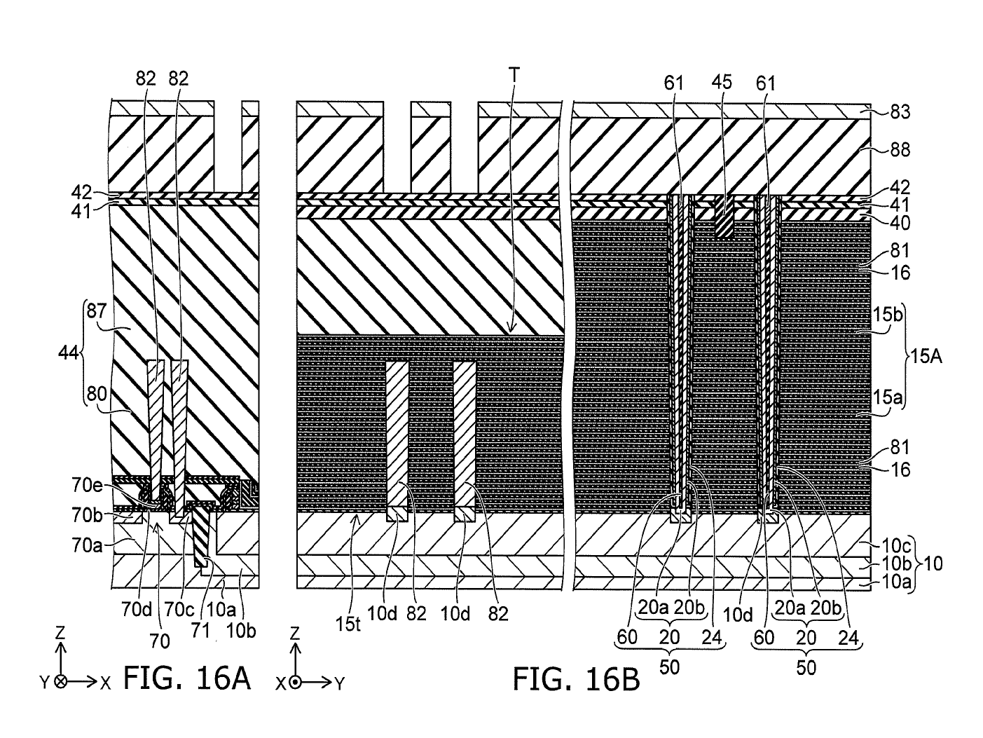

Next, as shown in FIGS. 16A and 16B, in the memory cell region Rm, the staircase region Rc, and the peripheral region Rp, an insulating layer 88 is formed on the insulating layer 42. A resist film 83 is formed on the insulating layer 88. Subsequently, in the staircase region Rc and the peripheral region Rp, the resist film 83 is patterned. Part of the insulating layer 88 is removed by etching processing using the resist film 83 as a mask. Thus, the upper surface of the insulating layer 42 is exposed.

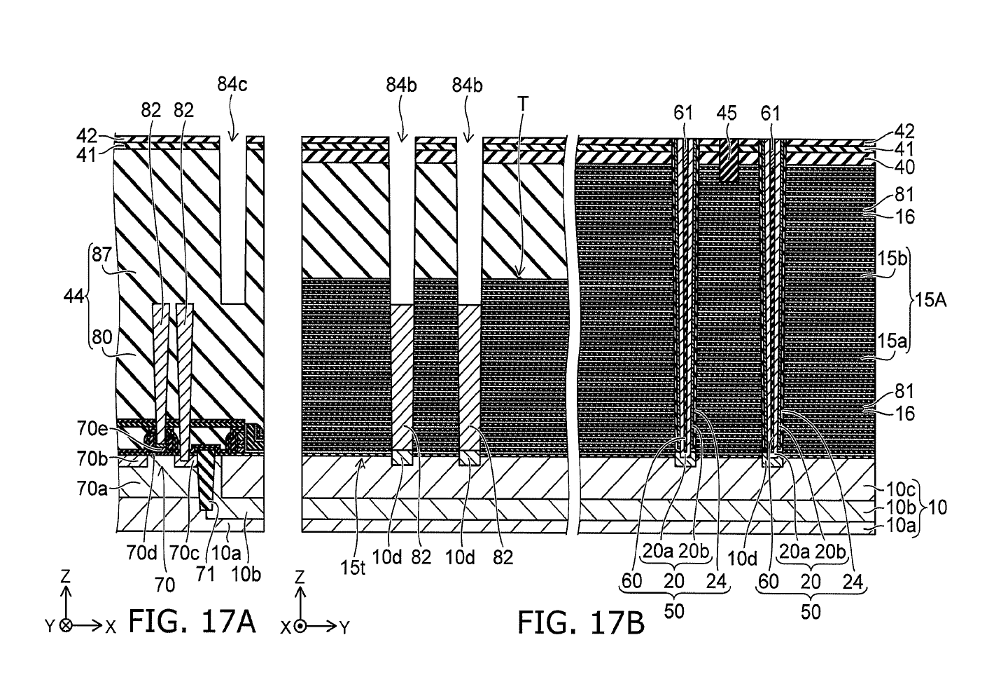

Next, as shown in FIGS. 17A and 17B, in the staircase region Rc and the peripheral region Rp, etching processing is performed from the exposed upper surface of the insulating layer 42. Then, in the memory cell region Rm, the staircase region Rc, and the peripheral region Rp, the insulating layer 88 and the resist film 83 are removed. Thus, a hole 84b located directly above the sacrificial layer 82 is formed in the staircase region Rc, and a hole 84c located in the insulating layer 44 is formed in the peripheral region Rp.

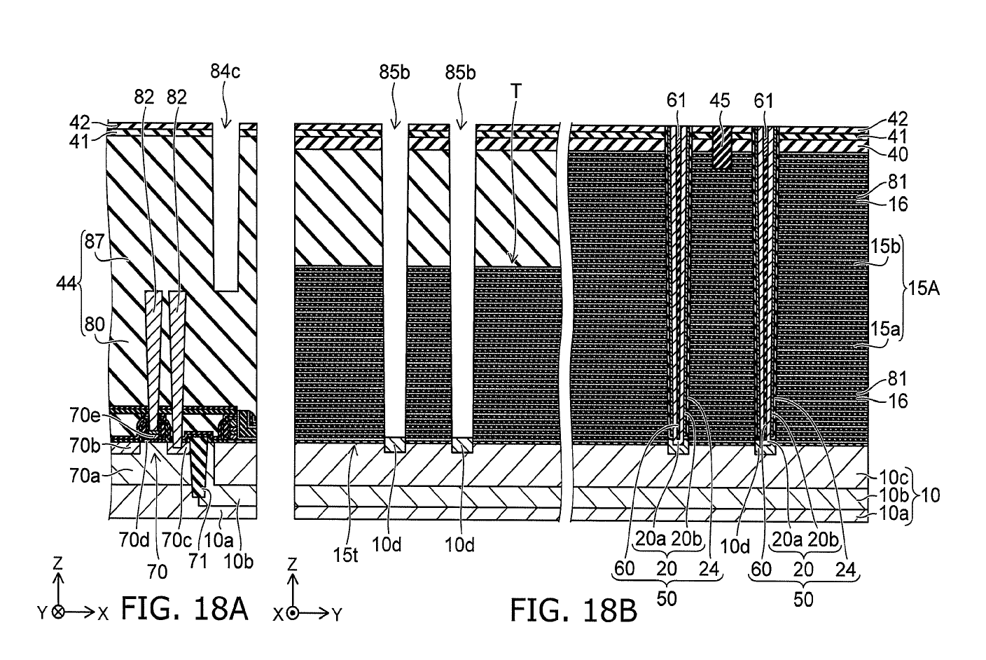

Next, as shown in FIGS. 18A and 18B, in the staircase region Rc, the sacrificial layer 82 located directly below the hole 84b is removed through the hole 84b. Thus, a through hole 85b is formed in the staircase region Rc.

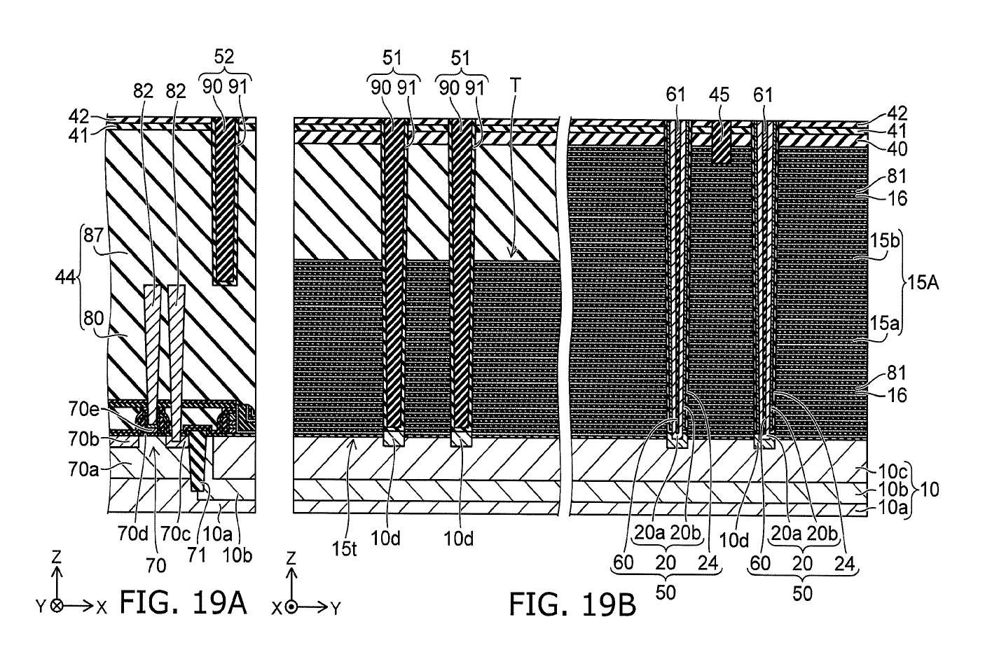

Next, as shown in FIGS. 19A and 19B, in the staircase region Rc and the peripheral region Rp, by e.g. the CVD method, on the inner surface of the through hole 85b and the hole 84c, silicon oxide is deposited to form an insulating film 91, and silicon nitride is deposited to form an insulating film 90. For instance, the bottom surface of the insulating film 91 of the columnar part 52 is in contact with the insulating layer 44.

The step of forming slits and the subsequent steps are the same as those of the first embodiment. However, in the case where the sacrificial layer 81 and the insulating film 90 contain silicon nitride, in the columnar part 51, the insulating film 91 is formed as a protective film on the bottom surface and the side surface of the insulating film 90. Thus, the insulating film 90 is not removed by the removal of the sacrificial layer 81 through the slits.

Thus, the semiconductor memory device 2 of this embodiment is manufactured.

Next, the effect of this embodiment is described.

In the semiconductor memory device 2 of this embodiment, the columnar part 52 includes an insulating film 90 and an insulating film 91. The insulating film 90 contains a material having a tensile stress (e.g. silicon nitride). The insulating film 91 is provided on the bottom surface and the side surface of the insulating film 90. Accordingly, the volume of the insulating layer 44 is decreased. Thus, the internal stress (e.g. compressive stress) by the insulating layer 44 is relaxed by the insulating film 90 to suppress warpage of the semiconductor substrate 10. This suppresses lowering of the processing accuracy in the manufacturing process.

The rest of the effect is the same as the effect of the first embodiment.

The embodiments described above can provide a semiconductor memory device and a manufacturing method thereof with improved reliability.

In the embodiments described above, the columnar part 52 is formed when forming the columnar part 50 and the columnar part 51. However, the embodiments are not limited thereto. For instance, as shown in FIGS. 4A and 4B, the columnar part 52 may be formed when the insulating member 45 is formed in the memory cell region Rm. In this case, trenches may be formed in the memory cell region Rm and the peripheral region Rp, and the formation material (e.g. silicon nitride) of the insulating member 45 may be buried in each trench.

For instance, the columnar part 52 may be formed when the interconnect part 18 is formed in the memory cell region Rm and the staircase region Rc. In this case, slits may be formed in the memory cell region Rm, the staircase region Rc, and the peripheral region Rp, and the formation material (e.g. metal such as tungsten) of the interconnect part 18 may be buried in each slit.

For instance, the columnar part 52 may be formed when the contacts 62, 63 are formed in the staircase region Rc and the peripheral region Rp, respectively. In this case, holes may be formed in the staircase region Rc and the peripheral region Rp, and the formation material (e.g. metal such as tungsten) of the contacts 62, 63 may be buried in each hole.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions. Additionally, the embodiments described above can be combined mutually.

What is claimed is:

1. A semiconductor memory device comprising:
a substrate;
a stacked body provided on the substrate and including a plurality of electrode layers stacked with spacing from each other;
a circuit section provided on the substrate and located in a second region adjacent to a first region provided with the stacked body;
a first insulating layer provided in the second region; and
a first columnar part provided in the second region and extending in a stacking direction of the plurality of electrode layers, the first insulating layer being located between the first columnar part and the circuit section.

2. The device according to claim 1, wherein a lower surface and a side surface of the first columnar part are surrounded with the first insulating layer.

3. The device according to claim 1, further comprising:
a second columnar part provided in the stacked body and extending in the stacking direction,
wherein the first columnar part contains a material formed in the second columnar part.

4. The device according to claim 1, wherein the first columnar part contains silicon.

5. The device according to claim 1, wherein the first columnar part includes a semiconductor part having a lower surface in contact with the first insulating layer.

6. The device according to claim 1, further comprising:
a third columnar part provided in an end part of the stacked body and extending in the stacking direction,
wherein the end part is shaped like a staircase in which a terrace is formed for each of the electrode layers, and
the first columnar part contains a material formed in the third columnar part.

7. The device according to claim 1, wherein the first columnar part contains silicon nitride.

8. The device according to claim 1, wherein the first columnar part includes a first insulating film containing silicon nitride, and a second insulating film provided on a side surface and a bottom surface of the first insulating film and containing silicon oxide.

9. The device according to claim 1, wherein
the end part of the stacked body is shaped like a staircase in which a terrace is formed for each of the electrode layers, and
the first insulating layer is located on the end part and formed from TEOS as a raw material.

10. A semiconductor memory device comprising:
a substrate;
a stacked body provided on the substrate and including a plurality of electrode layers stacked with spacing from each other;
a first columnar part provided in the stacked body and extending in a stacking direction of the plurality of electrode layers;
a second columnar part provided in a staircase-shaped end part of the stacked body in which a terrace is formed for each of the electrode layers, extending in the stacking direction, and located in a second region adjacent to a first region provided with the first columnar part;
a circuit section provided on the substrate and located in a third region, the second region being located between the third region and the first region;
a first insulating layer provided in the third region; and
a third columnar part provided in the third region and extending in the stacking direction, the first insulating layer being located between the third columnar part and the circuit section.

11. The device according to claim 10, wherein a lower surface and a side surface of the third columnar part are surrounded with the first insulating layer.

12. The device according to claim 10, wherein the third columnar part contains a material formed in the first columnar part.

13. The device according to claim 10, wherein the third columnar part contains a material formed in the second columnar part.

14. The device according to claim 10, wherein the first columnar part, the second columnar part, and the third columnar part contain a same material.

15. The device according to claim 10, wherein the third columnar part contains silicon.

16. The device according to claim 10, wherein the third columnar part includes a semiconductor part having a lower surface in contact with the first insulating layer.

17. The device according to claim 10, wherein the third columnar part includes a first insulating film containing silicon nitride, and a second insulating film provided on a side surface and a bottom surface of the first insulating film and containing silicon oxide.

18. A method for manufacturing a semiconductor memory device, comprising:
forming a circuit section in a first region on a substrate;
forming a first stacked body by alternately stacking first insulating layers and first layers in a second region on the substrate;
forming a second insulating layer on the circuit section; and
forming in the first stacked body a first through hole extending in a stacking direction of the first stacked body to the substrate, and forming in the second insulating layer a first hole extending in the stacking direction and having a bottom surface located in the second insulating layer.

19. The method according to claim 18, further comprising:
forming a semiconductor part in the first through hole and the first hole.

20. The method according to claim 18, further comprising:
forming a silicon nitride film in the first through hole and the first hole.
